(19) United States
(12) Patent Application Publication
(10) Pub. No.: US 2026/0248025 A1
(43) Pub. Date: Aug. 20, 2026

(54) SEMICONDUCTOR DEVICE AND METHOD FOR MANUFACTURING SEMICONDUCTOR DEVICE

(71) Applicant: Asahi Kasei Microdevices Corporation, Tokyo (JP)

(72) Inventors: Ayano IMIGI, Tokyo (JP); Saki USHIDA, Tokyo (JP)

(21) Appl. No.: 19/530,238

(22) Filed: Feb. 4, 2026

(30) Foreign Application Priority Data
Feb. 14, 2025 (JP) 2025-021943
Dec. 17, 2025 (JP) 2025-260658

(51) Int. Cl. H10W 74/10; H10W 70/06; H10W 70/655; H10W 70/685; H10W 72/00; H10W 74/01; H10W 90/00; H10W 90/20; G01N 21/3504; H10F 39/00; H10H 29/01; H10H 29/85; H10H 29/853; H10H 29/854

(52) U.S. Cl. CPC H10W 74/117; H10W 70/06; H10W 70/655; H10W 70/685; H10W 72/823; H10W 74/019; H10W 90/291; H10W 90/724; G01N 21/3504; H10F 39/804; H10F 39/811; H10H 29/0362; H10H 29/0364; H10H 29/853; H10H 29/854; H10H 29/857; H10W 90/401; H10W 90/794

(57) ABSTRACT

Provided is a semiconductor device including: an encapsulation layer which includes a semiconductor chip and an electrode pillar disposed to face a side surface of the semiconductor chip with a resin interposed therebetween; and a first redistribution layer which is provided on a first surface of the encapsulation layer, in which the first redistribution layer includes a first conductive portion which electrically connects a first terminal portion, which is provided on a first surface of the semiconductor chip facing the first surface of the encapsulation layer and exposed on the first surface of the encapsulation layer, and one end surface of the electrode pillar exposed on the first surface of the encapsulation layer.

### CROSS REFERENCE TO RELATED APPLICATIONS

The contents of the following patent application(s) are incorporated herein by reference:

NO. 2025-021943 filed in JP on February 14, 2025

NO. 2025-260658 filed in JP on December 17, 2025

### BACKGROUND

### Technical Field

The present invention relates to a semiconductor device and a method for manufacturing the semiconductor device.

### Related Art

Patent Document 1 describes a technique in which "in an image sensor in which an electrode needs to be led out to a side opposite to a substrate, the electrode is led out to a semiconductor substrate side without requiring a through-wiring technique". Patent Document 2 describes a technique of "an image sensor or a package for high-power LSIs that is provided with a glass substrate or a high-heat-dissipation substrate on one surface and leads out an external electrode from an opposite surface thereto". Patent Document 3 describes a technique in which "when manufacturing chip-size double-sided connection packages that allow for freely combining other packages of similar configuration above and below, processes requiring equipment close to the front-end process are consolidated into components offline". Patent Document 4 describes a technique for "providing a semiconductor package that can achieve miniaturization in a memory package in which a plurality of semiconductor memory chips are electrically connected by TSVs".

### Related Art Documents

### Patent Documents

Patent Document 1: Japanese Patent Application Publication No. 2009-70882

Patent Document 2: Japanese Patent No. 5690466

Patent Document 3: Japanese Patent No. 5820911

Patent Document 4: Japanese Patent Application Publication No. 2020-68264

### BRIEF DESCRIPTION OF THE DRAWINGS

FIG. 1 illustrates an example of a cross-sectional view of a semiconductor device 500 according to an embodiment.

FIG. 2A is an example of a plan view of the semiconductor device 500 of FIG. 1 from which a substrate 60 and a ball terminal 62 are removed, as viewed from a surface 510a side of an encapsulation layer 510.

FIG. 2B is an example of a plan view of the semiconductor device 500 of FIG. 1 as viewed from a surface 510b side of the encapsulation layer 510.

FIG. 3 illustrates an example of a cross-sectional view of the semiconductor device 500 according to the embodiment.

FIG. 4A is an example of a plan view of the semiconductor device 500 of FIG. 3 from which the substrate 60 and the ball terminal 62 are removed, as viewed from the surface 510a side of the encapsulation layer 510.

FIG. 4B is an example of a plan view of the semiconductor device 500 of FIG. 3 as viewed from the surface 510b side of the encapsulation layer 510.

FIG. 5 illustrates an example of a plan view of the semiconductor device 500.

FIG. 6 illustrates an example of the cross-sectional view of the semiconductor device 500 according to the embodiment.

FIG. 7 illustrates an example of a plan view of the semiconductor device 500 of FIG. 6.

FIG. 8 illustrates an example of the cross-sectional view of the semiconductor device 500 according to the embodiment.

FIG. 9 illustrates an example of the cross-sectional view of the semiconductor device 500 according to the embodiment.

FIG. 10 illustrates an example of the cross-sectional view of the semiconductor device 500 according to the embodiment.

FIG. 11 illustrates an example of the cross-sectional view of the semiconductor device 500 according to the embodiment.

FIG. 12A illustrates an example of a method for manufacturing the semiconductor device 500.

FIG. 12B illustrates an example of the method for manufacturing the semiconductor device 500 subsequent to FIG. 12A.

FIG. 12C illustrates an example of the method for manufacturing the semiconductor device 500 subsequent to FIG. 12B.

FIG. 13A illustrates an example of the method for manufacturing the semiconductor device 500.

FIG. 13B illustrates an example of the method for manufacturing the semiconductor device 500 subsequent to FIG. 13A.

### DESCRIPTION OF EXEMPLARY EMBODIMENTS

Hereinafter, the present invention will be described through embodiments of the invention, but the following embodiments do not limit the invention according to the claims. Further, not all of combinations of features described in the embodiments are essential to the solving means of the invention.

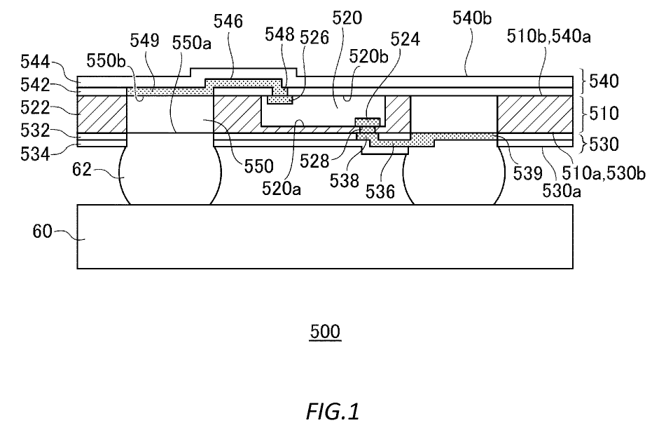

FIG. 1 illustrates an example of a cross-sectional view of a semiconductor device 500 according to the embodiment. The semiconductor device 500 is a semiconductor device used as a gas sensor or the like including an optical element. The semiconductor device 500 includes an encapsulation layer 510, redistribution layers 530 and 540, a substrate 60, and a ball terminal 62 connecting the substrate 60 and the encapsulation layer 510.

The encapsulation layer 510 is a layer that functions as a substrate as a whole by molding a semiconductor chip 520 with an encapsulation portion 522. The encapsulation portion 522 may be an encapsulation resin. The encapsulation layer 510 may be a reconstituted substrate. The encapsulation layer 510 has a surface 510a facing the redistribution layer 530 and a surface 510b opposite to the surface 510a and facing the redistribution layer 540. In addition, the encapsulation layer 510 includes the semiconductor chip 520, the encapsulation portion 522, a bump 528, and an electrode pillar 550.

As an example, the semiconductor chip 520 functions as a gas sensor. For example, the semiconductor chip 520 is a non-dispersive infrared (NDIR) gas sensor. The NDIR gas sensor is a sensor utilizing a characteristic that a gas molecule to be detected absorbs infrared light having a specific wavelength. In the NDIR gas sensor, a light-emitting element that radiates infrared light and a light-receiving element that receives the infrared light radiated and emitted from the light-emitting element are mounted. When a concentration of target gas molecules is high, the infrared light emitted from the light-emitting element is absorbed by the gas, and hardly reaches the light-receiving element. The NDIR gas sensor can detect the concentration of the target gas by measuring a transmittance of the infrared light from the light-emitting element to the light-receiving element. For example, the NDIR gas sensor is used to detect concentrations of carbon dioxide (CO₂), methane (CH₄), and the like. Therefore, the semiconductor chip 520 may include optical elements such as the light-emitting element and the light-receiving element of the NDIR gas sensor.

Note that, when the semiconductor chip 520 implements the NDIR gas sensor, the semiconductor chip 520 may include an optical filter (not illustrated) having a function of selectively transmitting an electromagnetic wave in a desired wavelength range to an optical element (particularly, the light-receiving element). A material constituting the optical filter may be a material that transmits an electromagnetic wave in a preset wavelength range, such as Si, SiO₂, sapphire (Al₂O₃), Ge, ZnS, ZnSe, CaF₂, or BaF₂. In addition, the optical filter may be configured to include a thin film member provided by vapor deposition or the like. The thin film material may include Si, SiO₂, sapphire (Al₂O₃), Ge, ZnS, TiO₂, MgF₂, ZrO₂, Ta₂O₅, or the like.

As another example, a photoacoustic gas sensor that detects, by using photoacoustic spectroscopy, an acoustic signal which is generated when gas molecules absorb light of a specific wavelength is provided as an optical gas sensor. In the photoacoustic gas sensor, a light-emitting element performs pulse irradiation with laser light, and a sound waves generated by thermal expansion of gas having absorbed the laser light is measured with a micro-electro-mechanical system (MEMS) microphone. The photoacoustic gas sensor is also used to detect concentrations of carbon dioxide (CO₂), methane (CH₄), or the like. The optical element included in the semiconductor chip 520 may be the light-emitting element of the photoacoustic gas sensor. The gas sensor mounted on the semiconductor chip 520 may be such a photoacoustic gas sensor, or may be another type of a gas sensor. The semiconductor chip 520 may include an optical element for a gas sensor using such an optical method.

The semiconductor chip 520 is provided on the surface 510a of the encapsulation layer 510, and one surface of the semiconductor chip 520 or a terminal portion electrically connected to the semiconductor chip is exposed on the surface 510a of the encapsulation layer 510. Accordingly, the semiconductor chip 520 can be connected to a conductive portion in the redistribution layer 530, and can be connected to the electrode pillar 550 by the conductive portion in the redistribution layer 530. The semiconductor chip 520 includes a surface 520a on a side facing the redistribution layer 530 and a surface 520b opposite to the surface 520a. The semiconductor chip 520 is connected to a redistribution layer on two surfaces 520a and 520b. One surface 520a of the semiconductor chip 520 is connected directly to the substrate 60, and the other surface 520b is connected to the substrate 60 via the electrode pillar 550, so that a current path through which a current flows via the semiconductor chip 520 can be provided in the semiconductor chip 520. By forming a system in which a current uniformly flows in the semiconductor chip 520, it is possible to prevent concentration of the current in the semiconductor chip 520, and an effect is obtained which suppresses local heat generation of the semiconductor chip 520.

In the semiconductor device 500 of the present embodiment, the semiconductor chip 520 may have, on the surface 520a facing the redistribution layer 530, a semiconductor stacked portion that achieves a function provided by the semiconductor chip 520. That is, the semiconductor chip 520 which is an optical sensor has the semiconductor stacked portion as an optical sensor on the surface 520a.

The encapsulation portion 522 is an encapsulation resin for encapsulating the semiconductor chip 520 and the electrode pillar 550 to form the encapsulation layer 510. As an example, the encapsulation portion 522 is an epoxy resin.

A terminal 524 is a terminal provided on the surface 520a of the semiconductor chip 520. The terminal 524 may be a terminal collectively referring to a plurality of terminals on the surface 520a on a side where the redistribution layer 530 is provided in the semiconductor chip 520. The terminal 524 may be provided, as an example, so as to be embedded in the semiconductor chip 520 and may be provided such that at least a part of the terminal 524 is exposed from the semiconductor chip 520. A material of the terminal portion may be different from or the same as a metal forming the conductive portion of the redistribution layer 530.

A terminal 526 is a terminal provided on the surface 520b of the semiconductor chip 520. The terminal 526 is a terminal that provides an electrical contact with the semiconductor chip 520 on the surface 520b of the semiconductor chip 520, and similarly to the terminal 524, may be provided so as to be embedded in the semiconductor chip 520 and may be provided such that at least a part of the terminal 526 is exposed from the semiconductor chip 520. The terminal 526 may be a terminal collectively referring to a plurality of terminals on the surface 520b on a side where the redistribution layer 540 is provided in the semiconductor chip 520. When the redistribution layer 540 is directly connected to the semiconductor chip 520, a place where a connection surface of the semiconductor chip 520 to the redistribution layer 540 is in contact with the redistribution layer 540 may constitute the terminal portion. The terminal 526 is an example of a "second terminal portion".

The bump 528 electrically connects the terminal 524 and the redistribution layer 530. The terminal 524 and the bump 528 integrally constitute a "terminal portion". The terminal portion is an example of a "first terminal portion".

The redistribution layer 530 includes a conductive portion that electrically connects the bump 528 and an end surface 550a of the electrode pillar 550 exposed on the surface 510a of the encapsulation layer 510. Specifically, the conductive portion has a contact electrically connected to the terminal 524 via the bump 528 and a contact electrically connected to the end surface 550a of the electrode pillar 550, and electrically connects these contacts. Note that the encapsulation layer 510 may have a structure in which the bump 528 is omitted, and the conductive portion may be directly connected to the terminal 524. The redistribution layer 530 includes a surface 530b facing the encapsulation layer 510 and a surface 530a facing the surface 530b. Note that the surface 530b may refer to a surface flush with the surface 510a. The redistribution layer 530 includes insulating layers 532 and 534 and a conductive portion. The conductive portion includes a conductive pattern layer 536, a connection portion 538, and a metal layer 539. The conductive pattern layer 536, the connection portion 538, and the metal layer 539 are examples of a "first conductive portion".

The semiconductor device 500 includes the ball terminal 62 which is provided at the surface 530a opposite to the surface 530b of the redistribution layer 530 on the encapsulation layer 510 side and is electrically connected to the redistribution layer 530. In this case, the surface 530a opposite to the surface 530b of the redistribution layer 530 facing the surface 510a of the encapsulation layer 510 may be a mounting surface on which the semiconductor device 500 is mounted on the substrate 60 by the ball terminal 62.

The insulating layers 532 and 534 constitute a part of the redistribution layer 530 and protect the conductive pattern layer 536 and the like. Since the semiconductor chip 520 is a semiconductor chip including an optical element, the insulating layers 532 and 534 are made of a light-transmitting resin. Therefore, the redistribution layer 530 includes, in at least a part of a region facing the semiconductor chip 520, a transmission region made of a transmission material that transmits light from an outside of the redistribution layer 530 to the semiconductor chip 520 or transmits light emitted from the semiconductor chip 520 to the outside of the redistribution layer 530.

As an example, the insulating layers 532 and 534 are made of a phenol resin. For example, when the NDIR gas sensor is used as the semiconductor chip 520, a transparent phenol resin may be used, but the resin used as the insulating layers 532 and 534 of the redistribution layer 530 is not limited to the transparent phenol resin. A material of the insulating layers 532 and 534 may be selected based on, for example, transmittance of an electromagnetic wave in a wavelength or frequency band targeted by the semiconductor chip 520 including an optical element. For example, when the semiconductor chip 520 implements the NDIR gas sensor, the insulating layers 532 and 534 may be made of a resin having light transmissivity for infrared light having a specific wavelength of 780 nanometers to 100 micrometers. As described above, in the semiconductor chip 520, in at least a part of the region facing the semiconductor chip 520, the transmission region made of the transmission material that transmits the light from the outside of the redistribution layer 530 to the semiconductor chip 520 or transmits the light emitted from the semiconductor chip 520 to the outside of the redistribution layer 530 may be selected based on the transmittance of the electromagnetic wave in the wavelength or frequency band targeted by the semiconductor chip 520 including the optical element.

Furthermore, the material of the insulating layers 532 and 534 may be selected in consideration of heat resistance, moisture resistance, mechanical strength, gas barrier properties, and the like, according to an environment in which the semiconductor chip 520 is used. In consideration of these, an encapsulation material made of a material different from the transparent phenol resin may be used as the material of the insulating layers 532 and 534.

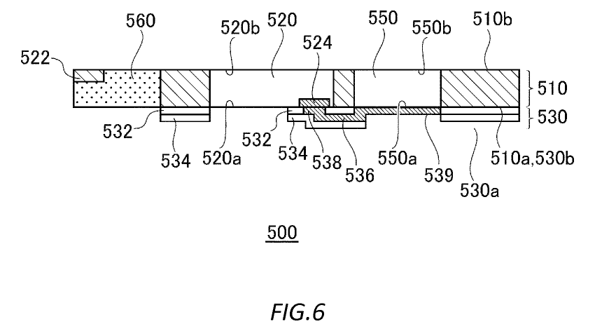

The transmission region may be provided by a method other than the method in which, in the semiconductor chip 520, the transmission region made of a transmission material is provided in at least a part of the region facing the semiconductor chip 520. For example, the transmission region may be provided by providing an uncovered region on the surface of the semiconductor chip 520 that is not covered with the redistribution layer 530 including the insulating layers 532 and 534. FIG. 6 described later is an example in which the transmission region is provided by providing, on the surface of the semiconductor chip 520, a region that is not covered with the redistribution layer 530 including the insulating layers 532 and 534.

The conductive pattern layer 536 is a metal pattern that extends from the semiconductor chip 520 to the outside of the semiconductor chip 520 in the redistribution layer 530 and transfers voltage, current, and power. Therefore, the redistribution layer 530 including the conductive pattern layer 536 has a so-called fan-out structure. As an example, the conductive pattern layer 536 is a conductive pattern layer made of a metal containing copper or the like. As an example, the conductive pattern layer 536 is formed by electroless plating of copper or the like after a seed layer 590 of nickel (Ni) and/or copper (Cu) or the like is disposed.

The connection portion 538 is a metal layer for connecting the bump 528 and the conductive pattern layer 536. The connection portion 538 may be provided integrally with the conductive pattern layer 536 by one process. When the bump 528 is omitted, the terminal 524 may be provided so as to be flush with the surface 520a of the semiconductor chip 520, and the conductive pattern layer 536 and the connection portion 538 may be directly connected to the terminal 524.

The metal layer 539 is a metal layer for connecting the electrode pillar 550 and the ball terminal 62. As an example, the metal layer 539 is formed by electroless plating of a metal, which has excellent solder wettability and is chemically stable, such as nickel (Ni) or gold (Au).

The redistribution layer 540 is provided on the surface 510b opposite to the surface 510a of the encapsulation layer 510. The redistribution layer 540 includes a conductive portion electrically connected to the terminal 526 provided on the surface 520b opposite to the surface 520a of the semiconductor chip 520. The redistribution layer 540 includes a surface 540a facing the encapsulation layer 510 and a surface 540b facing the surface 540a. Note that the surface 540a may refer to a surface flush with the surface 510b. The redistribution layer 540 includes insulating layers 542 and 544 and a conductive portion. The conductive portion includes a conductive pattern layer 546, a connection portion 548, and a metal layer 549. The conductive pattern layer 546, the connection portion 548, and the metal layer 549 are examples of a "second conductive portion".

The insulating layers 542 and 544 constitute a part of the redistribution layer 540 and protect the conductive pattern layer 546 and the like. As an example, the insulating layers 542 and 544 are made of a phenol resin. A material of the insulating layers 542 and 544 may be similar to the material of the insulating layers 532 and 534. When the semiconductor chip 520 includes an optical element, which of the surfaces 520a and 520b of the semiconductor chip 520 is to be the semiconductor stacked portion that achieves the function provided by the semiconductor chip 520 differs depending on a design. Therefore, at least on the semiconductor stacked portion side of the semiconductor chip 520, any one of the insulating layers 532 and 534 or the insulating layers 542 and 544 may be provided by a resin having light transmissivity. In this case, the insulating layer of the redistribution layer provided on the surface of the semiconductor chip 520 not including the optical element may be made of a different material, for example, may be made of a resin having no light transmissivity.

The conductive pattern layer 546 is a metal pattern that extends from the semiconductor chip 520 to the outside of the semiconductor chip 520 in the redistribution layer 540 and transfers voltage, current, and power. Therefore, the redistribution layer 540 including the conductive pattern layer 546 also has a fan-out structure similarly to the redistribution layer 530. Similarly to the conductive pattern layer 546, the conductive pattern layer 546 is a conductive pattern layer made of a metal containing copper or the like.

The connection portion 548 is a metal layer for connecting the terminal 526 and the conductive pattern layer 546. The connection portion 548 may be provided integrally with the conductive pattern layer 546 by one process.

The metal layer 549 is a metal layer for connecting the electrode pillar 550 and the conductive pattern layer 546. When the electrode pillar 550 is not connected to an external configuration, the metal layer 549 may be provided to have a configuration similar to that of the conductive pattern layer 546, and may be provided in one process together with the conductive pattern layer 546.

The redistribution layers 530 and 540 of the present embodiment have a configuration including a cured insulating resin as the insulating layers 532, 534, 542, and 544, and do not have a configuration including a substrate such as a photosensitive substrate of a glass substrate. In particular, in a chip first configuration described later, the redistribution layers 530 and 540 have a configuration formed by applying a resin. Therefore, in a sensor using an optical element, unlike a configuration in which a sensor surface is protected by using a substrate having light transmissivity such as a glass substrate, a thickness of the redistribution layer 530 can be remarkably reduced.

The thickness of the redistribution layer 530 provided can be equal to or less than 0.3 mm. Furthermore, the thickness of the redistribution layer 530 may be equal to or less than 0.16 mm. Note that this thickness can be provided to be thinner than a thickness of a mold used in a semiconductor package known as a quad flat non-leaded (QFN) package, for example. As described above, in the encapsulation layer 510, the redistribution layer 530 is used for connection without using electrical connection by a bonding wire or the like. Accordingly, the thickness of the insulating layers 532 and 534 can be reduced. Furthermore, a signal path can be shortened, and signal quality can be improved.

For example, when the semiconductor device 500 is used for the application of a gas sensor, the semiconductor device 500 may be exposed to heat during use due to operation or environmental factors. The semiconductor chip 520, the redistribution layer 530, and the like constituting the semiconductor device 500 can have different thermal expansion coefficients. In this case, thermal stress may be generated by thermal expansion, and/or thermal contraction of a member, or the like. Then, when the semiconductor device 500 is used for a long period of time, fatigue may accumulate at a bonding place or the like between materials, and deflection and/or distortion, or the like may occur in the member to generate stress. In addition, deterioration and the like may occur due to moisture absorption in a use environment and gas permeation, and mechanical characteristics of the member may be changed. In such a case, stress concentration may occur inside the semiconductor device 500. When the redistribution layer 530 can be provided thin, it becomes easy to provide the entire redistribution layer 530 with a more uniform film thickness, and flexibility increases more easily than when the insulating layer is provided thick. Such stress concentration in the semiconductor device 500 is mitigated. Accordingly, occurrence of variations in sensor characteristics can also be suppressed. Furthermore, the use of the thin redistribution layer 530 is also advantageous for miniaturization of a package using the semiconductor device 500, and the like.

The thickness of the redistribution layer 540 may also be set similarly to the redistribution layer 530. Therefore, the thickness of the redistribution layer 540 provided can be equal to or less than 0.3 mm. Furthermore, the thickness of the redistribution layer 540 may be equal to or less than 0.16 mm. Accordingly, the thickness of the insulating layers 532 and 534 can be reduced. Therefore, the redistribution layer 540 can also contribute to mitigating the stress concentration in the encapsulation layer 510, miniaturizing the package using the semiconductor device 500, and the like.

In the metal layers 539 and 549 of the present embodiment, connection to a structure outside the encapsulation layer 510 can be implemented by terminals provided on both surfaces of the encapsulation layer 510. Accordingly, a degree of integration of the encapsulation layer 510 and the entire semiconductor package using the semiconductor device 500 can be increased, and the entire package can be miniaturized.

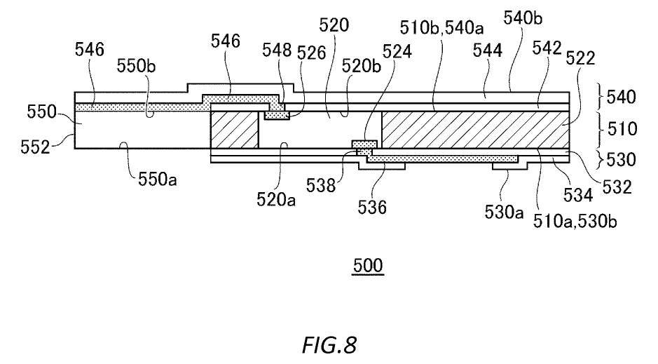

The electrode pillar 550 is disposed to face a side surface of the semiconductor chip 520 with the encapsulation portion 522 interposed therebetween. The electrode pillar 550 has the end surface 550a exposed from the encapsulation layer 510, on the surface 510a of the encapsulation layer 510, and the end surface 550b opposite to the end surface 550a. The electrode pillar 550 has a hard metal pillar structure, and is disposed so as to sandwich the semiconductor chip 520 with the encapsulation portion 522 interposed therebetween. Sandwiching the semiconductor chip 520 with such hard metal electrode pillar 550 prevents chip cracking of the semiconductor chip 520 and increases the strength of the package. The electrode pillar 550 may be provided as a post electrode without drilling the encapsulation portion 522, but may be provided as a so-called through-mold via (TMV) as an electrode penetrating the encapsulation portion 522. The electrode pillar 550 may be used as an electrode pillar for supplying power to the semiconductor chip 520 in order for the semiconductor chip 520 to operate, or may be used as an electrode pillar 550 for providing a conductive path to transfer a signal read from the semiconductor chip 520 to the outside of the semiconductor chip 520. As an example, the electrode pillar 550 contains a metal such as copper. In this case, the electrode pillar 550 may be manufactured by electrolytic copper plating. In addition, particularly, as will be described later with reference to FIG. 8, the electrode pillar 550 can also be provided in a structure in which a part is exposed from the encapsulation layer 510. The electrode pillar 550 may also function as a path to conduct, to the outside, heat generated when the semiconductor chip 520 operates, and particularly when the electrode pillar 550 has a structure exposed to the outside of the encapsulation layer 510, the electrode pillar 550 functions as a structure for efficiently promoting heat dissipation. In addition, the electrode pillar 550 may be exposed on both sides of the first surface 520a and the second surface 520b of the semiconductor chip 520. Accordingly, heat dissipation paths can be provided on both sides of the surface 520a side and the surface 520b side of the semiconductor device 500.

When the semiconductor chip 520 is configured as a package on which a gas sensor including an optical sensor is mounted, it is conceivable to configure a ceramic package in consideration of excellent thermal conductivity and mechanical strength. Since the electrode pillar 550 can provide a path excellent even in heat dissipation, when used in combination with the ceramic package, a highly reliable sensor can be provided even in a high-temperature and/or high-temperature environment in which a gas sensor can be used.

In the drawing, a plurality of electrode pillars 550 are disposed in the encapsulation layer 510. As described above, the semiconductor device 500 may include the plurality of electrode pillars 550 disposed in the encapsulation layer 510. In this case, at least two electrode pillars of the plurality of electrode pillars may be electrically connected. In addition, accordingly, the plurality of electrode pillars may be set to a same potential.

In an embodiment different from the present embodiment, the semiconductor chip 520 has, on the surface 520b opposite to the surface 520a facing the redistribution layer 530, a semiconductor stacked portion that achieves the function provided by the semiconductor chip 520. In this case, the surface 530a opposite to the surface 530b of the redistribution layer 530 facing the surface 510a of the encapsulation layer 510 may be a mounting surface of the semiconductor device 500 on which the semiconductor device 500 is mounted on the substrate 60.

The surface 510a of the encapsulation layer 510 is an example of a "first surface" of the encapsulation layer 510, and the surface 510b is an example of a "second surface" of the encapsulation layer 510. The surface 520a of semiconductor chip 520 is an example of the "first surface" of the semiconductor chip 520, and the surface 520b is an example of the "first surface" of the semiconductor chip 520.

The redistribution layer 530 is an example of a "first redistribution layer". On the other hand, the redistribution layer 540 is an example of a "second redistribution layer".

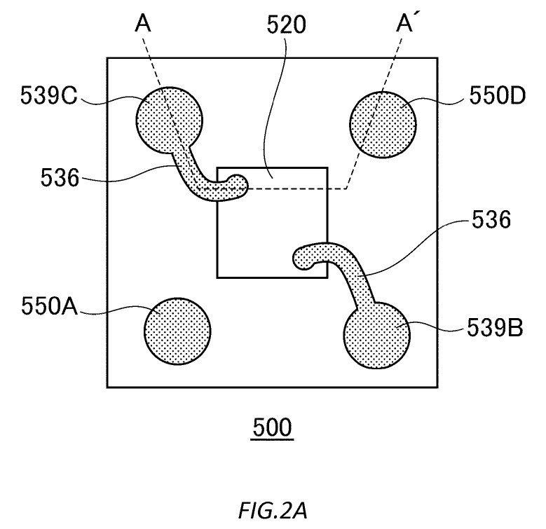

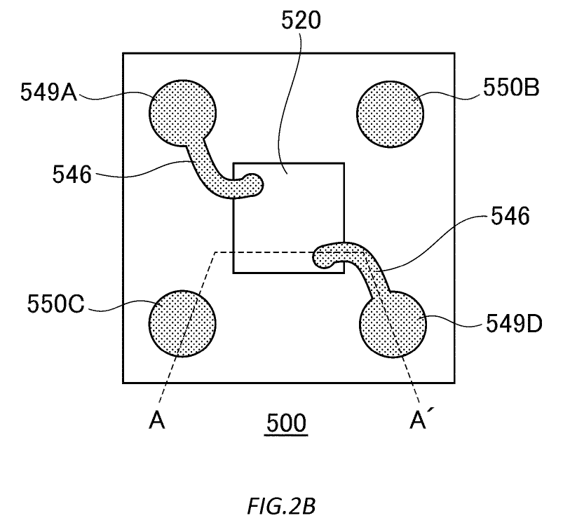

FIG. 2A is an example of a plan view of the semiconductor device 500 of FIG. 1 from which the substrate 60 and the ball terminal 62 are removed, as viewed from the surface 510a side of the encapsulation layer 510.

The electrode pillar 550 is provided such that a terminal comes out from both surfaces of the semiconductor chip 520. In the semiconductor device 500 of the present embodiment, the redistribution layers 530 and 540 are provided on both surfaces of the encapsulation layer 510, respectively.

The redistribution layer 530 electrically connects the semiconductor chip 520 and electrode pillars 550B and 550C, and the metal layer 539 is exposed at positions of the electrode pillars 550B and 550C. On the other hand, no metal layer is provided at positions of electrode pillars 550A and 550D, and end surfaces of the electrode pillars 550A and 550D are exposed as they are.

FIG. 2B is an example of a plan view of the semiconductor device 500 in FIG. 1 as viewed from the surface 510b side of encapsulation layer 510. Each of the redistribution layers 530 and 540 electrically connects the semiconductor chip 520 and the electrode pillar 550.

The redistribution layer 540 electrically connects the semiconductor chip 520 and the electrode pillars 550B and 550C, and the metal layer 549 is exposed at the positions of the electrode pillars 550B and 550C. On the other hand, no metal layer is provided at the positions of the electrode pillars 550A and 550D, and the electrode pillars 550A and 550D are exposed as they are. In the present embodiment, an electrical connection relationship between the semiconductor chip 520 and the electrode pillars 550A, 550B, 550C, and 550D is reversed between the surface 510a and the surface 510b of the encapsulation layer 510. The electrical connection relationship between the semiconductor chip 520 and the electrode pillars 550 is not limited as illustrated in the drawing, and some of the electrode pillars 550 may be connected to any of the conductive portions of the redistribution layers 530 and 540. In addition, some of the metal layers 549 constituting any of the redistribution layers 530 and 540 may not be connected to the electrode pillar 550 (any of the electrode pillars 550A, 550B, 550C, or 550D). Note that FIG. 1 is an example of an A-A' cross-sectional view taken along line A-A’ illustrated in FIGS. 2A and 2B.

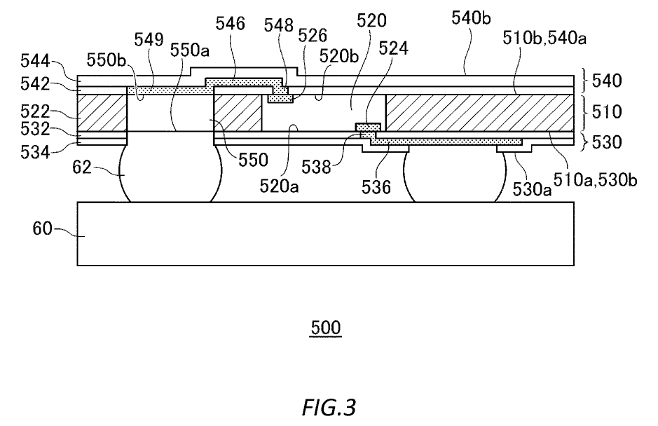

FIG. 3 illustrates an example of a cross-sectional view of the semiconductor device 500 according to the embodiment. Hereinafter, description will be given mainly focusing on a difference from the semiconductor device 500 of the embodiment of FIGS. 1, 2A, and 2B. The semiconductor device 500 according to the present embodiment includes the encapsulation layer 510, the redistribution layer 530, and the redistribution layer 540.

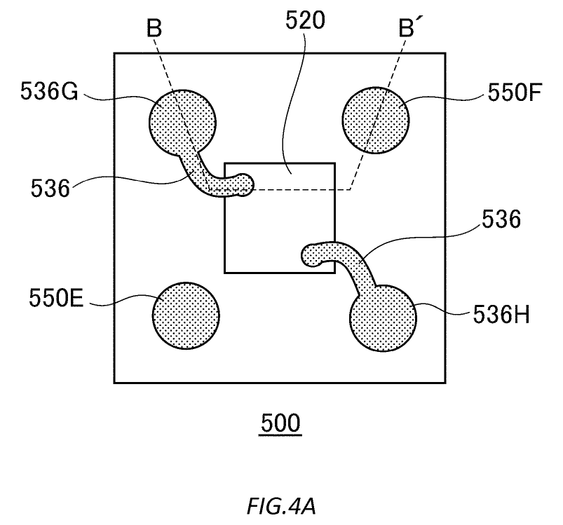

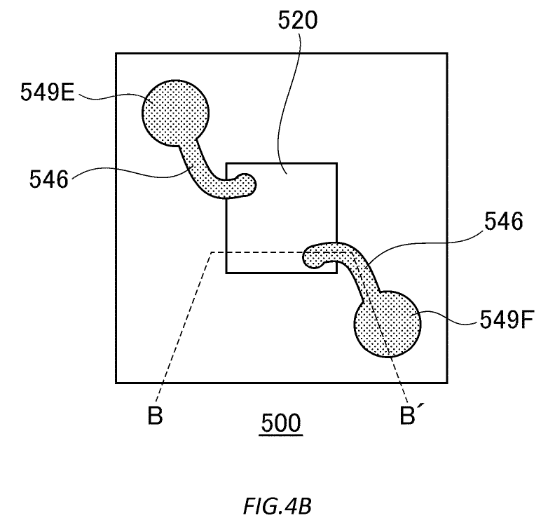

FIG. 4A is an example of a plan view of the semiconductor device 500 of FIG. 3 from which the substrate 60 and the ball terminal 62 are removed, as viewed from the surface 510a side of the encapsulation layer 510.

In the present embodiment, electrode pillars are not provided at places corresponding to conductive pattern layers 536G and 536H, and only conductive pattern layers are provided. On the other hand, two electrode pillars 550 of electrode pillars 550E and 550F are provided.

The semiconductor chip 520 may be electrically connected to the outside of the encapsulation layer 510 (for example, to the substrate 60) via the conductive pattern layers 536G and 536H.

FIG. 4B is an example of a plan view of the semiconductor device 500 of FIG. 3 as viewed from the surface 510b side of the encapsulation layer 510. In FIG. 4A, at places where the conductive pattern layers 536G and 536H are provided, nothing is provided when viewed from a side of FIG. 4B. Note that FIG. 3 is an example of a B-B' cross-sectional view taken along line B-B’ illustrated in FIGS. 4A and 4B.

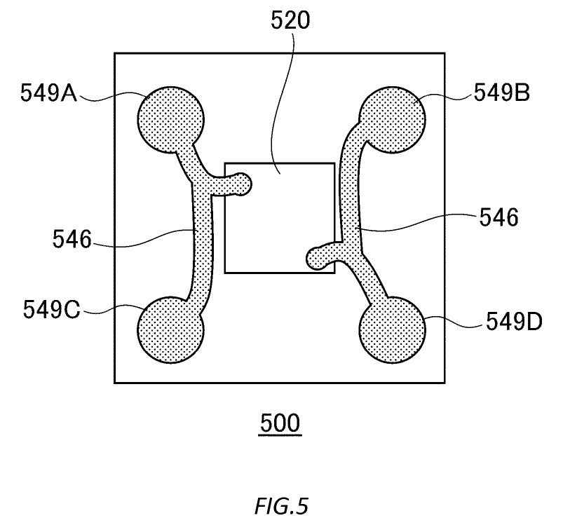

FIG. 5 illustrates an example of a plan view of the semiconductor device 500. FIG. 5 is an example of a plan view of the semiconductor device 500 from which the substrate 60 and the ball terminal 62 are removed, as viewed from the surface 510a side of the encapsulation layer 510.

In FIG. 5, a combination of the electrode pillars 550A and 550C and a combination of the electrode pillars 550B and 550D are each set to a same potential. Regarding a case where at least two electrode pillars among the plurality of electrode pillars are set to a same potential, this is an example in which the electrode pillar 550 is set to a potential different from that in the example of FIGS. 2A and 2B. As described above, the electrode pillar 550 functions not only as an electrical connection path but also as a thermal conduction path. Therefore, as an example of using the electrode pillars 550 having the same potential, for example, there is a use method in which a plurality of electrode pillars 550 having a ground potential is provided to promote heat dissipation from a plurality of ground paths.

FIG. 6 illustrates an example of a cross-sectional view of the semiconductor device 500 according to the embodiment. The semiconductor device 500 includes the encapsulation layer 510 and the redistribution layer 530. Hereinafter, description will be given mainly focusing on a difference from the semiconductor device 500 of the embodiment of FIGS. 1, 2A and 2B. The encapsulation layer 510 in the present embodiment includes the semiconductor chip 520, the encapsulation portion 522, and a conductive structural body 560.

The conductive structural body 560 is a conductive structural body that is not electrically connected to the semiconductor chip 520 but is connected to an external conductive trace or the like. As an example, the conductive structural body 560 may have a composition similar to that of the electrode pillar 550. Therefore, the conductive structural body 560 may be provided by electrolytic plating of a metal such as copper.

The conductive structural body 560 is a conductive structural body through which a current that varies in magnitude according to a situation of a circuit connected to the outside flows. As an example, the semiconductor chip 520 is provided with a magnetic sensor functioning as a current sensor, and detects a magnetic field varying according to the magnitude of the current flowing in the conductive structural body 560. The magnetic sensor may include a Hall element or a magneto resistive element. The magneto resistive element may be a semiconductor magneto resistive (SMR) element, an anisotropic magneto resistive (AMR) element, a giant magneto resistive (GMR) element, a tunnel magneto resistive (TMR) element, or the like.

The conductive structural body 560 may be located at a position facing the side surface of the semiconductor chip 520 and be exposed on the side surface of the encapsulation layer 510. With such a configuration, the conductive structural body 560 can be connected to an external conductive trace or the like.

FIG. 6 illustrates a cross section intersecting the surface 520a of the semiconductor chip 520. The conductive structural body 560 divides the encapsulation portion 522 of the encapsulation layer 510 into two regions in this cross section. That is, the cross section illustrated in FIG. 6 is an example of a "first cross section" of the encapsulation layer 510. In the cross section of FIG. 6, on a surface side of the encapsulation layer 510 on a side where the redistribution layer 530 is not provided, the conductive structural body 560 divides the encapsulation portion 522 of the encapsulation layer 510 into two regions.

In addition, in the conductive structural body 560, a thickness of a portion exposed on the side surface of encapsulation layer 510 may be thinner than a thickness of the portion facing the side surface of semiconductor chip 520. Accordingly, dicing of the semiconductor device 500 is facilitated as described later.

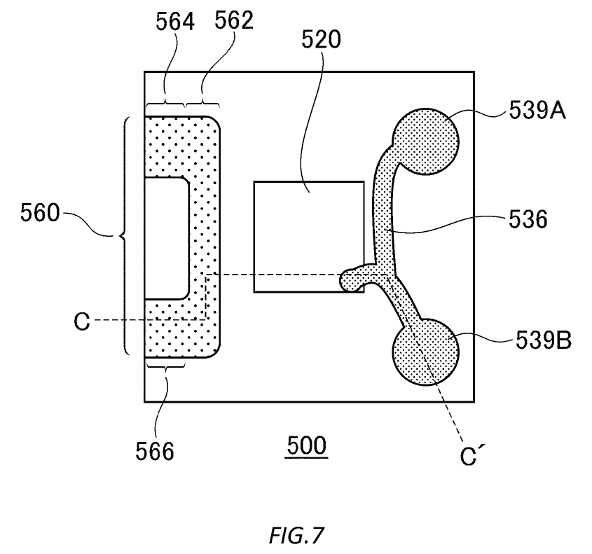

As illustrated in the drawing, the conductive structural body 560 has a portion having a reduced thickness in a portion close to the side surface of the encapsulation layer 510. These structures will be described in more detail with reference to FIG. 7.

FIG. 7 illustrates an example of a plan view of the semiconductor device 500 of FIG. 6. In the drawing, the plan view of the semiconductor device 500 as viewed from the redistribution layer 530 side is illustrated. FIG. 6 is an example of a C-C 'cross-sectional view taken along line C-C' illustrated in FIG. 7.

As for the conductive structural body 560, the conductive structural body 560 that extends so as to be exposed at one side of the semiconductor device 500 and has a U-shape is illustrated in the drawing. The conductive structural body 560 includes a first portion 562, a second portion 564, and a third portion 566 that extend to form the U-shape. As illustrated in the drawing, on the surface on the redistribution layer 530 side, the conductive structural body 560 divides the encapsulation portion 522 of the encapsulation layer 510 into two regions. Therefore, in at least one of the cross section of the encapsulation layer 510 intersecting the surface 520a of the semiconductor chip 520 or the surface on the redistribution layer 530 side, the conductive structural body 560 may divide the encapsulation portion 522 of the encapsulation layer 510 into two regions.

The conductive structural body 560 varies a magnetic field generated in the semiconductor chip 520 by causing a current to flow in a U-shape. The semiconductor chip 520 of the present embodiment includes a magnetic sensor, and detects the magnitude of the current flowing through the conductive structural body 560 by detecting the magnetic field varying according to the current flowing through the conductive structural body 560.

When viewed from the redistribution layer 530 side, the first portion 562 faces the side surface of the semiconductor chip 520 and extends in a direction along the side surface of the semiconductor chip 520. The first portion 562 corresponds to a portion in which the thickness does not vary in FIG. 6, but a part of the first portion 562 may also vary in thickness as it extends along the second portion 564 and the third portion 566.

When viewed from the redistribution layer 530 side, the second portion 564 extends from one end of the first portion in a direction away from the side surface of the semiconductor chip 520. When viewed from the redistribution layer 530 side, the third portion 566 extends from another end of the first portion in a direction away from the side surface of the semiconductor chip 520.

As illustrated in FIG. 6, each of the second portion 564 and the third portion 566 has a portion that has a thin thickness in a portion away from the side surface of the semiconductor chip 520 and close to the side surface of the encapsulation layer 510, as compared with its portion close to the first portion. Parts of the second portion 564 and the third portion 566 are exposed on the side surface of the encapsulation layer 510. The parts of the second portion 564 and the third portion 566 exposed on the side surface of the encapsulation layer 510 are thinner than the portions of the second portion 564 and the third portion 566 connected to the first portion 562. Accordingly, a length of a metal portion of the conductive structural body 560 to be cut and/or polished, or the like when the encapsulation layer 510 is diced is shortened, and the encapsulation layer 510 is easily diced. Accordingly, damage to a blade of a dicing device can also be reduced.

Note that, in the semiconductor device 500 according to the present embodiment, the electrode pillars 550A and 550B are connected to each other via the conductive pattern layer 546. Accordingly, the electrode pillars 550A and 550B are set to a same potential. In addition, the electrode pillars 550A and 550B may be used for external connection.

FIG. 8 illustrates an example of a cross-sectional view of the semiconductor device 500 according to the embodiment. Hereinafter, description will be given mainly focusing on a difference from the semiconductor device 500 of the embodiment of FIGS. 1, 2A and 2B.

In the electrode pillar 550 of the embodiment according to FIG. 8, at least a part of the side surface 552 of the electrode pillar 550 is exposed from the side surface of the encapsulation layer 510. This enables electrical connection from the side surface of the electrode pillar 550. For example, the side surface of the encapsulation layer 510 may be electrically connected to another structure by solder bonding. As described above, in the electrode pillar 550 of the present embodiment, the solder bonding appears on the side surface of the encapsulation layer 510, so that a bonded portion can be inspected based on its appearance, and the electrode pillar 550 is exposed to the outside, so that a heat dissipation effect is increased. Accordingly, a degree of freedom of electrical connection of the encapsulation layer 510 is also increased.

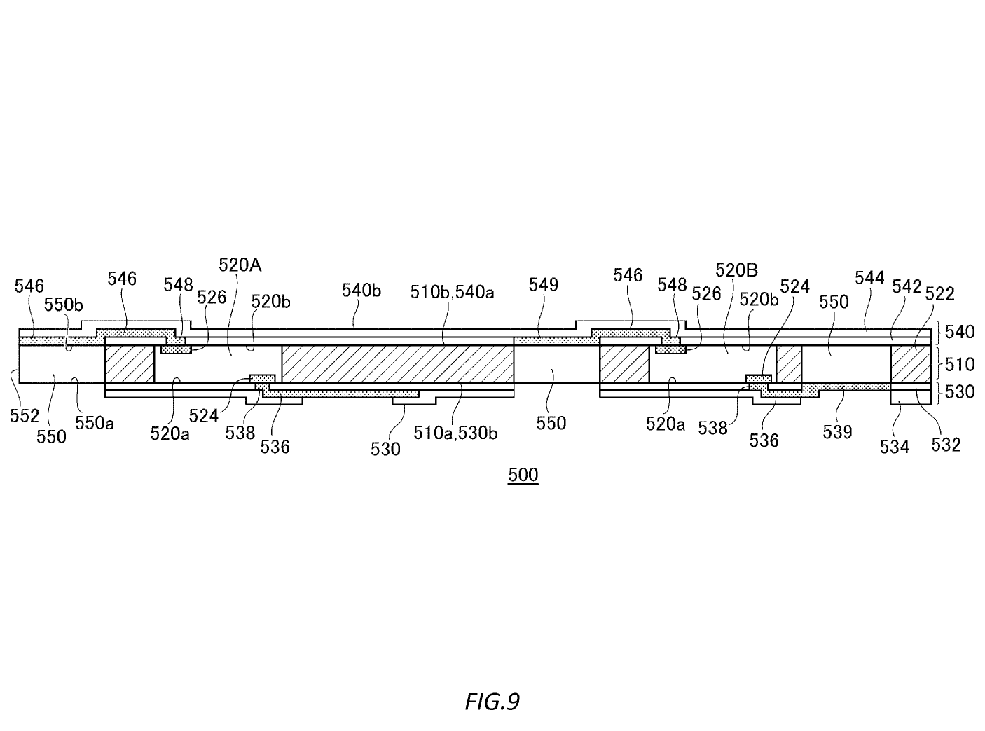

FIG. 9 illustrates an example of a schematic side view of the semiconductor device 500 according to the embodiment. The semiconductor device 500 according to the embodiment of FIG. 9 includes both the structure of the semiconductor device 500 according to FIG. 1 and the structure of the semiconductor device 500 according to FIG. 8 in an extending direction of the encapsulation layer 510.

As illustrated in the drawing, the encapsulation layer 510 includes a plurality of semiconductor chips 520A and 520B. In the present embodiment, the plurality of semiconductor chips 520A and 520B are provided along the extending direction of the encapsulation layer 510. The semiconductor chip 520A corresponds to the semiconductor chip 520 provided in the semiconductor device 500 according to the embodiment of FIG. 8. Therefore, in the drawing, the electrode pillar 550, the side surface 552 of which is exposed, is illustrated. On the other hand, the semiconductor chip 520B corresponds to the semiconductor chip 520 provided in the semiconductor device 500 according to the embodiment of FIG. 1.

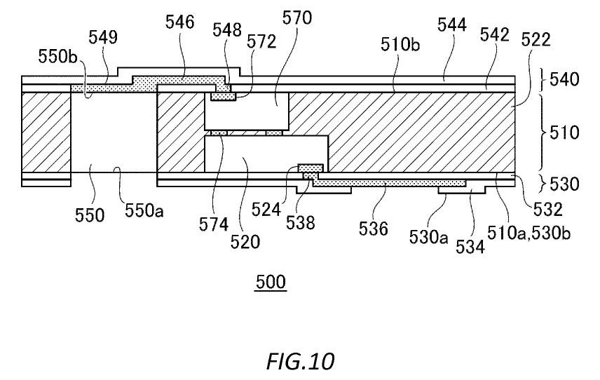

FIG. 10 illustrates an example of a schematic side view of the semiconductor device 500 according to the embodiment. The semiconductor device 500 includes semiconductor chips 520 and 570, the electrode pillar 550, and a bump 574.

The semiconductor device 500 according to the present embodiment also has a structure in which the encapsulation layer 510 includes a plurality of semiconductor chips 520 and 570. However, the semiconductor chips 520 and 570 are stacked in a thickness direction of the encapsulation layer 510, and are different from the structure of FIG. 9 in which a plurality of semiconductor chips are included in the extending direction of the encapsulation layer 510. The semiconductor chips 520 and 570 may be stacked with a bump interposed therebetween, or may be directly stacked with no bump interposed therebetween.

When a plurality of semiconductor chips are provided as in the encapsulation layer 510 in FIGS. 9 and 10, for example, the semiconductor chip 520 functions as a semiconductor chip on which an optical sensor is provided, and the semiconductor chip 570 functions as a signal processing chip that processes a signal based on a magnitude of a current detected by the optical sensor. As another example, the semiconductor chips 520 and 570 may implement another type of sensor, for example, the semiconductor chip 520 may implement a magnetic sensor, and the semiconductor chip 570 may implement an optical sensor. Since the semiconductor chips 520 and 570 are connected to each other via the bump 574, the semiconductor chips 520 and 570 can be implemented so as to perform processing using signals output from each other. In addition, the semiconductor chip 570 has a terminal 572 for electrical connection with the electrode pillar 550. The terminal 572 may function similarly to the terminals 524 and 526 and the like of the semiconductor chip 520.

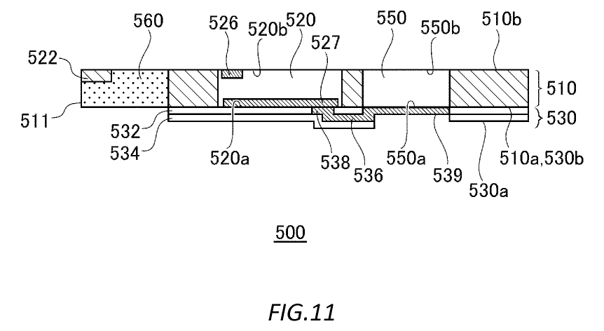

FIG. 11 illustrates an example of a cross-sectional view of the semiconductor device 500. In the present embodiment, description will be given mainly focusing on a difference from the semiconductor device 500 of the embodiment of FIG. 6.

Similarly to the embodiments described with reference to FIGS. 1 and 6, the semiconductor chip 520 has the surface 520b, which is a light incident surface of the semiconductor chip 520 exposed from the encapsulation layer 510, on the surface 510b of the encapsulation layer 510. In addition, the semiconductor chip 520 has the surface 520a, which is a surface opposite to the surface 520b and is exposed from the encapsulation layer 510, on the surface 510a of the encapsulation layer 510.

In the present embodiment, the semiconductor chip 520 is provided with the terminal 526 so as to have a contact on the surface 520b of the semiconductor chip 520. Similarly to the embodiment described with reference to FIG. 1, the terminal 526 is a terminal that provides an electrical contact with the semiconductor chip 520 on the surface 520b of the semiconductor chip 520, and similarly to the terminal 524, may be provided so as to be embedded in the semiconductor chip 520, and may be provided such that at least a part of the terminals 524 and 526 is exposed from the semiconductor chip 520. On the other hand, the surface 520a of the semiconductor chip 520 is covered with the redistribution layer 530.

Similarly to the embodiments described with reference to FIGS. 1 and 6, the electrode pillar 550 has the end surface 550a exposed from the encapsulation layer 510, on the surface 510a of the encapsulation layer 510, and the end surface 550b opposite to the end surface 550a. The semiconductor chip 520 includes a pad 527 electrically connected to the end surface 550b of the electrode pillar 550. Similarly to the terminals 524 and 526, the pad 527 is a terminal that provides an electrical contact with the semiconductor chip 520 on the surface 520a of the semiconductor chip 520, and similarly to the terminals 524 and 526, may be provided so as to be embedded in the semiconductor chip 520 and may be provided such that at least a part of the pad 527 is exposed from the semiconductor chip 520.

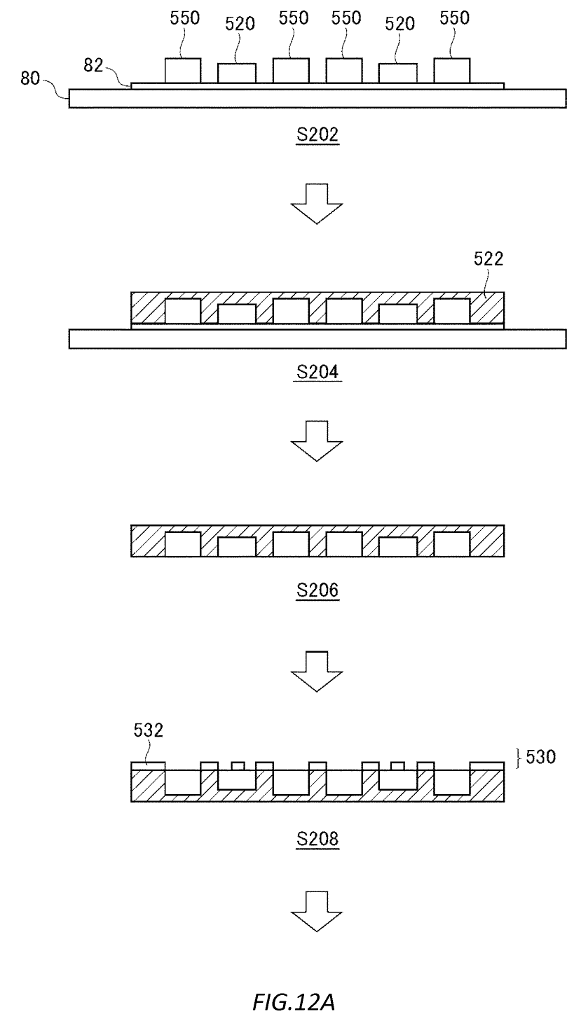

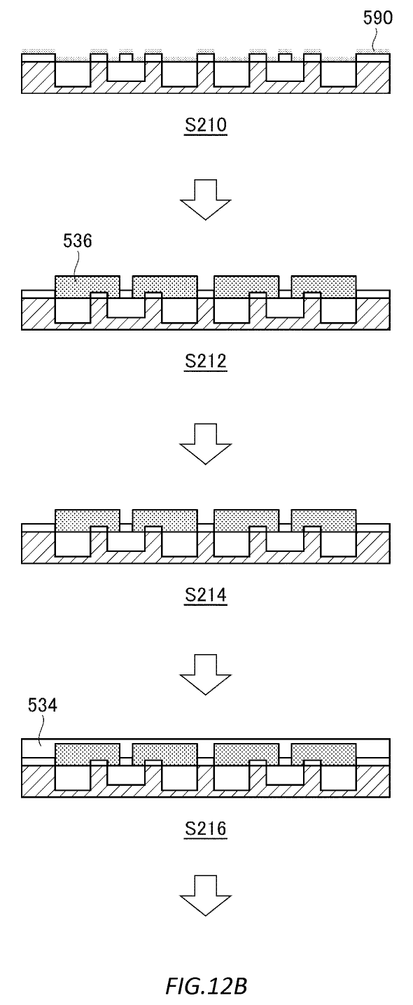

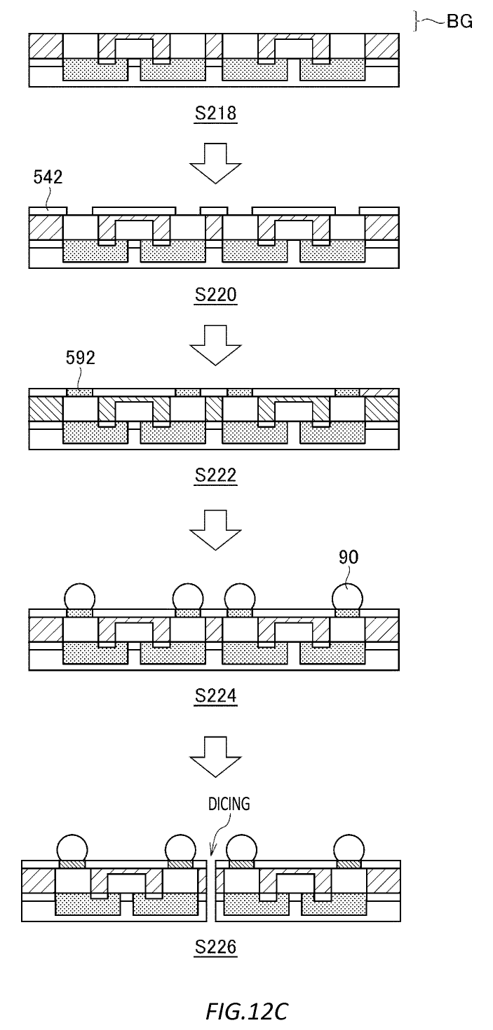

Also in the present embodiment, the redistribution layer 530 includes the insulating layers 532 and 534, the conductive pattern layer 536, which has conductivity and is provided inside the insulating layer 534, and the connection portion 538 electrically connecting the pad 524 and the conductive pattern layer 536. The connection portion 538 is provided in a through hole provided in the insulating layer 532 by electrolytic plating or the like with a seed layer. The insulating layer 532 covers a region of the surface 520a of the semiconductor chip 520 other than a region of the through hole where the connection portion 538 is provided. The insulating layer 534 is a layer provided as a protective layer of the conductive pattern layer 536 after the conductive pattern layer 536 is provided, and a manufacturing process thereof will be described later in detail with reference to FIGS. 12A to 12C and the like.

In the present embodiment, the ball terminal 62 may be provided on the terminal 526 and the end surface 550b of the electrode pillar 550. Accordingly, in this embodiment, the surface 520a of the semiconductor chip 520 is connected to the outside via the terminal 526 and the ball terminal 62. On the other hand, the surface 520b of the semiconductor chip 520 is connected to the outside via the ball terminal 62, the electrode pillar 550, the conductive pattern layer 536 in the redistribution layer 530, the connection portion 538, and the pad 527.

In the semiconductor device 500 according to the embodiment of FIG. 6, it has been described that the incident surface of light with respect to the semiconductor chip 520 is a surface on which the transmission region is provided in a region, which is not covered with the redistribution layer 530 including the insulating layers 532 and 534, in the surface of the semiconductor chip 520. Here, the light incident surface of the semiconductor chip 520 may be the surface 520a or the surface 520b of the semiconductor chip 520.

In the semiconductor chip 520 of the present embodiment, the surface 520b is the light incident surface of the semiconductor chip 520. The light incident surface of the semiconductor chip 520 may be formed as an optically transparent region in such a manner that a region not covered with the redistribution layer is provided on the surface 520b opposite to the surface 520a on which the redistribution layer 530 is provided with respect to the semiconductor chip 520, thereby uncovering the semiconductor chip 520.

In this case, the terminal 526 may not be directly connected to the redistribution layer. As described above, in the semiconductor device 500 of FIG. 11, the redistribution layer 530 is provided so as to cover one surface 520a of the surfaces of the semiconductor chip 520, and the transmission region not covered with the redistribution layer is provided on the other surface 520b.

In the present embodiment, in the semiconductor device 500, a surface on which the ball terminal 62 is provided in the terminal 526 and a surface corresponding to the light incident surface of the semiconductor chip 520 both correspond to the surface 520b of the semiconductor chip 520. In addition, in the semiconductor device 500, the surface of the electrode pillar 550 on which the ball terminal 62 is provided also becomes the end surface 550b, and corresponds to a surface facing a same direction in the semiconductor device 500.

FIG. 12A illustrates an example of a method for manufacturing semiconductor device 500. The method for manufacturing the semiconductor device 500 according to the present embodiment includes steps S202 to S226. In FIGS. 12A to 12C, the semiconductor chip 520 is provided before the redistribution layer. Such a manufacturing method is an example of a manufacturing method called chip first.

First, in the method for manufacturing the semiconductor device 500, a substrate 80 is installed and an adhesive layer 82 is attached. Further, the semiconductor chip 520 and the electrode pillar 550 are mounted on the adhesive layer 82 (S202). The adhesive layer 82 may be provided by an adhesive such as a water-soluble adhesive. The semiconductor chip 520 and the electrode pillar 550 are disposed spaced apart from each other on one surface of the substrate 80. As an example, the substrate 80 is made of silicon (Si).

Next, the encapsulation portion 522 is provided on the surface of the substrate 80 on which the semiconductor chip 520 and the electrode pillar 550 are disposed in a state where the semiconductor chip 520 and the electrode pillar 550 are disposed spaced apart from each other. Accordingly, the semiconductor chip 520 and the electrode pillar 550 are molded and encapsulated by the encapsulation portion 522 (S204). Accordingly, the encapsulation layer 510 which is a reconstituted substrate is obtained. That is, the reconstituted substrate corresponds to the encapsulation layer 510 formed in the chip-first manufacturing method.

Further, the substrate 80 and the adhesive layer 82 are peeled off from the encapsulation layer 510 (S206). As described above, the substrate 80 is a substrate that is peeled off after the semiconductor chip 520 is mold-encapsulated by the encapsulation portion 522, and is a substrate that temporarily supports the semiconductor chip 520 and the electrode pillar 550 as a sacrificial layer. Therefore, the substrate 80 is an example of a "temporary support substrate". Through the above, the encapsulation layer 510 is manufactured.

Next, the redistribution layer 530 is formed on the encapsulation layer 510. First, the insulating layer 532 is formed on the encapsulation layer 510 (S208). As an example, the insulating layer 532 is made of a phenol resin.

FIG. 12B illustrates an example of the method for manufacturing the semiconductor device 500 subsequent to FIG. 12A. The metal seed layer 590 of the conductive pattern layer 536 is provided (S210). The metal seed layer 590 may be provided by sputtering. As an example, a metal to be sputtered is titanium (titanium) or copper (Cu).

Next, a resist is applied onto the insulating layer 532, and then electrolytic plating is performed to form a metal layer for the conductive pattern layer 536 (S212). As an example, the electrolytic plating applied in S212 may be electrolytic copper plating.

Further, the conductive pattern layer 536 is formed by immersion of an etching solution (S214). As the etching solution, an etching solution in which an oxidizing agent and a complexing agent are appropriately selected may be used in consideration of materials of a mask and the conductive pattern layer 536, and the like.

Next, the insulating layer 534 for protecting the conductive pattern layer 536 is formed (S216). Through the above, the redistribution layer 530 is formed. Therefore, after the substrate 80 is peeled off from the encapsulation layer 510 on the surface of the encapsulation layer 510 on which the semiconductor chip 520 and the electrode pillar 550 are disposed, the redistribution layer 530 can be formed which electrically connects the terminal 524 provided on the surface 520a of the semiconductor chip 520 exposed on the surface 510a of the encapsulation layer 510 and one end surface (end surface 550a) of the electrode pillar 550 exposed from the surface 510a of the encapsulation layer 510.

FIG. 12C illustrates an example of the method for manufacturing the semiconductor device 500 subsequent to FIG. 12B.

Subsequently to S216, back grinding (BG) is performed on the encapsulation portion 522 until the end surface 550b of the electrode pillar 550 is exposed (S218). This step corresponds to a step of grinding the encapsulation portion 522 until the end surface 550b of the electrode pillar 550 is exposed from the surface 510b of the encapsulation layer 510 on the opposite side of the surface 510a.

The insulating layer 542 is formed (S220). The insulating layer 542 may be made of phenol. In this case, the insulating layer 544 and the conductive pattern layer 546 may be provided similarly to the surface 510a of the encapsulation layer 510. Accordingly, the redistribution layer 540 is provided.

Next, a metal layer 592 for disposing a ball terminal 90 is disposed (S222). The metal layer 592 may be made of a metal containing nickel (Ni), gold (Au), or the like, which has excellent solder wettability and high chemical stability.

The ball terminals 90 are mounted on the metal layer 592 (S224). Each semiconductor device 500 is singulated by dicing after the ball terminals 90 are mounted (S226). Accordingly, the semiconductor device 500 can be manufactured.

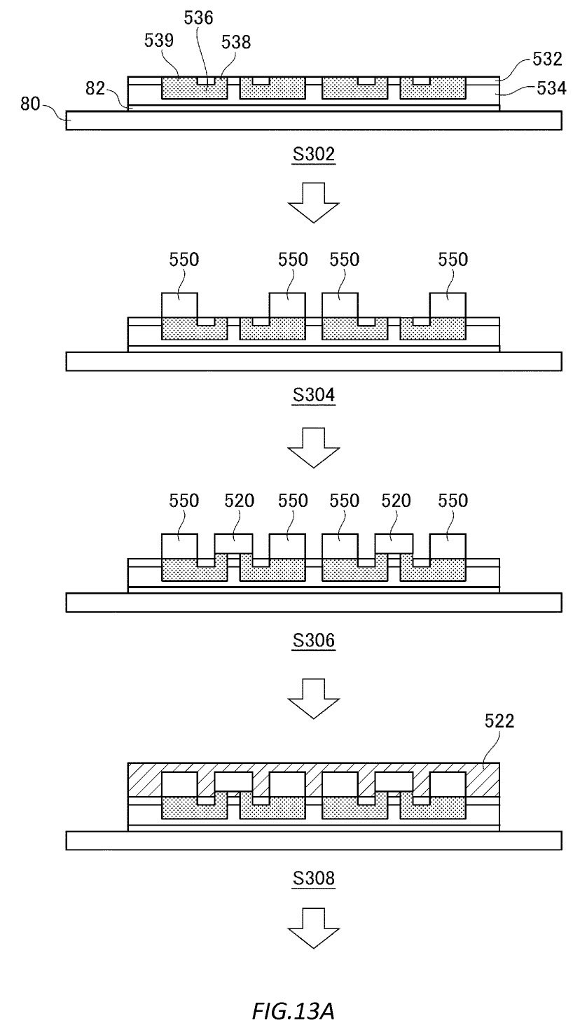

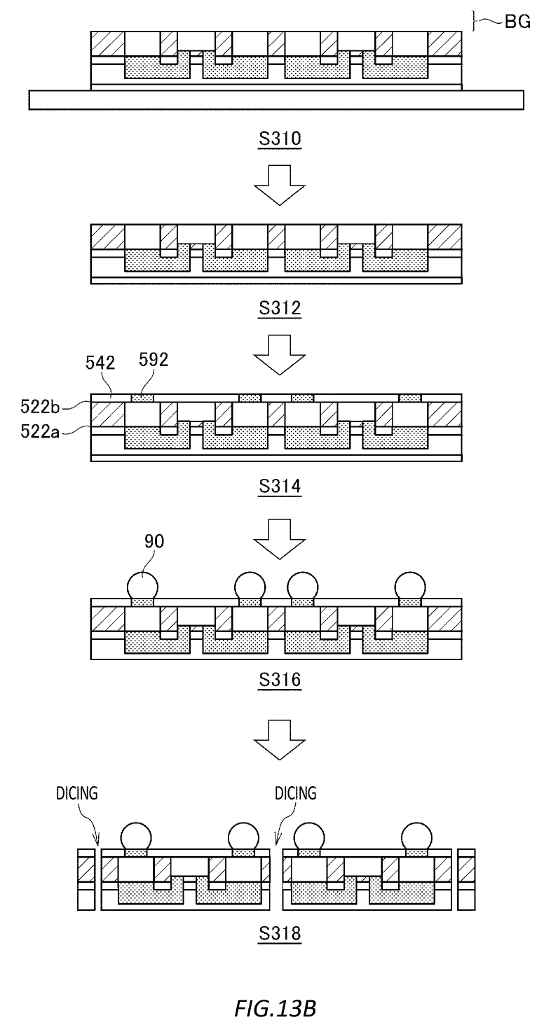

FIG. 13A illustrates an example of a method for manufacturing semiconductor device 500. The method for manufacturing the semiconductor device 500 according to the present embodiment includes steps S302 to S318. In the semiconductor device 500, the semiconductor chip 520 and the electrode pillar 550 are provided after the redistribution layer 530 is provided. Since the semiconductor chip 520 is provided after the redistribution layer 530, the method for manufacturing the semiconductor device 500 of the present embodiment is an example of a manufacturing method called chip last.

In the method for manufacturing the semiconductor device 500 according to the present embodiment, first, the adhesive layer 82 is provided on the substrate 80. Next, the insulating layer 534 provided with the conductive pattern layer 536 and the insulating layer 532 provided with the connection portion 538 including a conductor and the metal layer 539 are formed (S302). Accordingly, the redistribution layer 530 is formed on one surface of the substrate 80.

Next, the electrode pillar 550 is formed on the metal layer 539 (S304). Accordingly, the electrode pillar 550 electrically connected to the redistribution layer 530 is formed on the surface 530b (corresponding to the surface 510a of the encapsulation layer 510) opposite to the surface 530a of the redistribution layer 530 on the substrate 80 side.

Further, the semiconductor chip 520 with the bump 528 is die-bonded onto the connection portion 538 (S306). Accordingly, the semiconductor chip 520 electrically connected to the electrode pillar 550 via the redistribution layer 530 is disposed spaced apart from the electrode pillar 550 on the surface 530b (corresponding to the surface 510a of the encapsulation layer 510) opposite to the surface 530a of the redistribution layer 530 on the substrate 80 side. As described above, in the present embodiment, after the redistribution layer 530 is provided, the semiconductor chip 520 is disposed, thereby configuring the encapsulation layer 510.

Next, the semiconductor chip 520 and the electrode pillar 550 are molded and encapsulated by the encapsulation portion 522 (S308). Accordingly, in a state where the electrode pillar 550 and the semiconductor chip 520 are disposed spaced apart from each other, the surface 530b opposite to the surface 530a of the first redistribution layer 530 on the substrate 80 side, the other end surface 550b opposite to one end surface 550a of the electrode pillar 550 on the redistribution layer 530 side, and the surface 520b opposite to the surface 520a of the semiconductor chip 520 on the redistribution layer 530 side are encapsulated with the encapsulation portion 522. Also in the present embodiment, the encapsulation layer 510 in which the redistribution layer 530 similar to that after S216 is disposed is formed on the substrate 80 and the adhesive layer 82.

FIG. 13B illustrates an example of the method for manufacturing the semiconductor device 500 subsequent to FIG. 13A.

Subsequently to S308, back grinding (BG) is performed on the encapsulation portion 522 until the end surface 550b of the electrode pillar 550 is exposed (S310). Accordingly, the resin is ground until the other end surface 550b of the electrode pillar 550 is exposed.

Next, the encapsulation layer 510 is peeled off from the substrate 80 and the adhesive layer 82 (S312). The encapsulation layer 510 formed in S312 is similar to the encapsulation layer 510 after S218. In the present embodiment, a method for manufacturing the semiconductor device 500 to be performed later can be similar to the method on and after S220.

In the present embodiment, the encapsulation layer 510 is peeled off from the substrate 80 and the adhesive layer 82 after the back grinding in which the end surface 550b of the electrode pillar 550 is exposed, but a timing of peeling off the substrate 80 and the adhesive layer 82 is not limited to that after S310. For example, the process of peeling the substrate 80 and the adhesive layer 82 may be performed between S308 and S310. In this case, the encapsulation layer 510 and the redistribution layer 530 obtained after the substrate 80 and the adhesive layer 82 are peeled off are similar to those obtained after S216. As described above, the substrate 80 and the adhesive layer 82 may be peeled off from the encapsulation layer 510 at any timing at which the structure of the encapsulation layer 510 can be stabilized without temporary support by the substrate 80.

Next, the insulating layer 542 is formed on the encapsulation layer 510 and the redistribution layer 530, and the metal layer 592 for disposing the ball terminal 90 is disposed (S314). The insulating layer 542 may be made of phenol. Also in this case, the insulating layer 544 and the conductive pattern layer 546 may be provided similarly to the surface 510a of the encapsulation layer 510. Accordingly, the redistribution layer 540 is provided. Therefore, after the substrate 80 is peeled off from the encapsulation layer 510 on the surface 510a of the encapsulation layer 510 on which the semiconductor chip 520 and the electrode pillar 550 are disposed, the redistribution layer 540 which electrically connects the connection portion 548 and the electrode pillar 550 can be formed on the surface 522b opposite to the surface 522a of the encapsulation portion 522 on the redistribution layer 530 side, the end surface 550b of the electrode pillar 550, and the surface 520b opposite to the surface 520a of the semiconductor chip on the redistribution layer 530 side. Here, the metal layer 592 for disposing the ball terminal 90 may be made of a metal containing nickel (Ni), gold (Au), or the like, which has excellent solder wettability and high chemical stability.

The ball terminal 90 is mounted on the metal layer 592 (S316). Each semiconductor device 500 is singulated by dicing after the ball terminals 90 are mounted (S318). Accordingly, the semiconductor device 500 can be manufactured.

As described above, the semiconductor device 500 can be manufactured by any manufacturing method of the chip first or the chip last. Accordingly, it is possible to provide the semiconductor device 500 in which the redistribution layers 530 and 540 are thin and which can be compatible with a double-sided terminal package.

Accordingly, stress concentration occurring in the semiconductor device 500 can be mitigated, and a structure of the entire semiconductor package can be reduced. Furthermore, since the semiconductor device 500 can be compatible with a double-sided terminal package, a degree of freedom in design regarding electrical connection of the package is improved, and the semiconductor device 500 can be provided which is advantageous also in that efficient heat dissipation from the electrode pillar 550 can be provided.

While the embodiments of the present invention have been described, the technical scope of the present invention is not limited to the above-described embodiments. It is apparent to persons skilled in the art that various alterations or improvements can be added to the above-described embodiments. It is also apparent from the claims that the embodiments added with such alterations or improvements can be included in the technical scope of the present invention.

The operations, procedures, steps, and stages or the like of each process performed by an apparatus, system, program, and method shown in the claims, specification, or drawings can be performed in any order as long as the order is not indicated by "prior to," "before," or the like and as long as the output from a previous process is not used in a later process. Even if the process flow is described using phrases such as "first" or "next" in the claims, specification, and drawings, it does not necessarily mean that the process must be performed in this order.

### Other possible items

### Item 1

A semiconductor device including:

an encapsulation layer which includes a semiconductor chip and an electrode pillar disposed to face a side surface of the semiconductor chip with a resin interposed therebetween; and

a first redistribution layer which is provided on a first surface of the encapsulation layer, in which

the first redistribution layer includes a first conductive portion which electrically connects a first terminal portion, which is provided on a first surface of the semiconductor chip facing the first surface of the encapsulation layer and exposed on the first surface of the encapsulation layer, and one end surface of the electrode pillar exposed on the first surface of the encapsulation layer.

### Item 2

The semiconductor device according to item 1, in which

the first terminal portion includes a bump, and

the first terminal portion of the semiconductor chip and the first conductive portion are electrically connected via the bump.

### Item 3

The semiconductor device according to item 1, further including a ball terminal which is provided on a surface of the first redistribution layer opposite to a surface of the first redistribution layer on a side of the encapsulation layer or on the electrode pillar exposed to the first surface of the encapsulation layer and is electrically connected to the first conductive portion.

### Item 4

The semiconductor device according to item 1, in which a thickness of the first redistribution layer is equal to or less than 0.3 mm.

### Item 5

The semiconductor device according to item 1, further including a second redistribution layer which is provided on a second surface opposite to the first surface of the encapsulation layer and includes a second conductive portion electrically connected to a second terminal portion provided on a second surface opposite to the first surface of the semiconductor chip.

### Item 6

The semiconductor device according to item 5, in which

a current path is formed between the first conductive portion and the second conductive portion with the semiconductor chip interposed therebetween.

### Item 7

The semiconductor device according to item 5, in which a part of a side surface of the electrode pillar is exposed from a side surface of the encapsulation layer.

### Item 8

The semiconductor device according to item 1, in which the first redistribution layer includes, in at least a part of a region facing the semiconductor chip, a transmission region made of a transmission material that transmits light from an outside of the first redistribution layer to the semiconductor chip or transmits light emitted from the semiconductor chip to the outside of the first redistribution layer.

### Item 9

The semiconductor device according to item 1, including

a plurality of electrode pillars, each being the electrode pillar, which are disposed in the encapsulation layer, in which

at least two electrode pillars among the plurality of electrode pillars are electrically connected.

### Item 10

The semiconductor device according to item 5, in which

the semiconductor chip includes, on the first surface facing the first redistribution layer, a semiconductor stacked portion that achieves a function provided by the semiconductor chip, and

a surface of the first redistribution layer opposite to a surface of the first redistribution layer facing the first surface of the encapsulation layer is a mounting surface of the semiconductor device.

### Item 11

The semiconductor device according to item 5, in which

the semiconductor chip includes, on a second surface opposite to the first surface facing the first redistribution layer, a semiconductor stacked portion that achieves a function provided by the semiconductor chip, and

a surface of the first redistribution layer opposite to a surface of the first redistribution layer facing the first surface of the encapsulation layer is a mounting surface of the semiconductor device.

### Item 12

The semiconductor device according to item 1, in which the encapsulation layer includes a plurality of semiconductor chips each being the semiconductor chip.

### Item 13

The semiconductor device according to item 12, in which the plurality of semiconductor chips are stacked in a thickness direction of the encapsulation layer.

### Item 14

The semiconductor device according to item 8, in which the semiconductor chip includes an optical element.

### Item 15

The semiconductor device according to item 5, in which

the encapsulation layer has a conductive structural body that is located at a position facing a side surface of the semiconductor chip and is exposed on a side surface of the encapsulation layer.

### Item 16

The semiconductor device according to item 15, in which

the conductive structural body divides an encapsulation portion encapsulating the semiconductor chip in the encapsulation layer into two regions in at least one of a first cross section of the encapsulation layer intersecting the first surface of the semiconductor chip or a surface on a side of the first redistribution layer.

### Item 17

The semiconductor device according to item 15 or 16, in which

in the conductive structural body, a thickness of another portion exposed on the side surface of the encapsulation layer is thinner than a thickness of one portion facing the side surface of the semiconductor chip.

### Item 18

The semiconductor device according to item 5, in which the encapsulation layer further includes a conductive structural body that has a first portion facing a side surface of the semiconductor chip and extending in a direction along the side surface of the semiconductor chip, a second portion extending from one end of the first portion in a direction away from the side surface of the semiconductor chip, and a third portion extending from another end of the first portion in a direction away from the side surface of the semiconductor chip.

### Item 19

The semiconductor device according to item 18, in which a part of the second portion and a part of the third portion are exposed on a side surface of the encapsulation layer, and a thickness of the part of the second portion and a thickness of the part of the third portion are thinner than that of the first portion.

### Item 20

A method for manufacturing a semiconductor device, including:

forming an encapsulation layer by encapsulating one surface of a temporary support substrate with a resin in a state where a semiconductor chip and an electrode pillar are disposed spaced apart from each other on the one surface of the temporary support substrate;

after the temporary support substrate is peeled off from a first surface of the encapsulation layer, on the first surface of the encapsulation layer,

forming a first redistribution layer which electrically connects a first terminal portion provided on a first surface of the semiconductor chip exposed on the first surface of the encapsulation layer and one end surface of the electrode pillar exposed from the first surface of the encapsulation layer;

grinding the resin until another end surface of the electrode pillar is exposed from a second surface opposite to the first surface of the encapsulation layer; and

forming a second redistribution layer which is electrically connected to the another end surface of the electrode pillar on the second surface of the encapsulation layer from which the another end surface of the electrode pillar is exposed.

### Item 21

A method for manufacturing a semiconductor device, including:

forming a first redistribution layer on one surface of a temporary support substrate;

forming an electrode pillar, which is electrically connected to the first redistribution layer, on a surface of the first redistribution layer opposite to a surface of the first redistribution layer on a side of the temporary support substrate;

disposing a semiconductor chip, which is electrically connected to the electrode pillar via the first redistribution layer, spaced apart from the electrode pillar on the surface of the first redistribution layer opposite to the surface of the first redistribution layer on the side of the temporary support substrate;

encapsulating, with a resin, the surface of the first redistribution layer opposite to the surface of the first redistribution layer on the side of the temporary support substrate, another end surface of the electrode pillar opposite to one end surface of the electrode pillar on a side of the first redistribution layer, and a surface of the semiconductor chip opposite to a surface of the semiconductor chip on the side of the first redistribution layer in a state where the electrode pillar and the semiconductor chip are disposed spaced apart from each other;

grinding the resin until the another end surface of the electrode pillar is exposed; and

after the temporary support substrate is peeled from the first redistribution layer, forming a second redistribution layer, which is electrically connected to the electrode pillar, on a surface of the resin opposite to a surface of the resin on the side of the first redistribution layer, the another end surface of the electrode pillar, and the surface of the semiconductor chip opposite to the surface of the semiconductor chip on the side of the first redistribution layer.

### EXPLANATION OF REFERENCES

60: substrate;

62, 90: ball terminal;

80: substrate;

82: adhesive layer;

500: semiconductor device;

510: encapsulation layer;

510a, 510b: surface;

520: semiconductor chip;

520a, 520b: surface;

522: encapsulation portion;

522a, 522b: surface;

524, 526, 572: terminal;

527: pad;

528: bump;

530, 540: redistribution layer;

530a, 530b: surface;

532, 534, 542, 544: insulating layer;

536, 546: conductive pattern layer;

538, 548: connection portion;

539, 549: metal layer;

540a, 540b: surface;

550: electrode pillar;

550a, 550b: end surface;

552: side surface;

560: conductive structural body;

562: first portion;

564: second portion;

566: third portion;

570: semiconductor chip;

574: bump;

590: seed layer; and

592: metal layer.

What is claimed is:

1. A semiconductor device comprising:
an encapsulation layer which includes a semiconductor chip and an electrode pillar disposed to face a side surface of the semiconductor chip with a resin interposed therebetween; and
a first redistribution layer which is provided on a first surface of the encapsulation layer, wherein
the first redistribution layer includes a first conductive portion which electrically connects a first terminal portion, which is provided on a first surface of the semiconductor chip facing the first surface of the encapsulation layer and exposed on the first surface of the encapsulation layer, and one end surface of the electrode pillar exposed on the first surface of the encapsulation layer.

2. The semiconductor device according to claim 1, wherein
the first terminal portion includes a bump, and
the first terminal portion of the semiconductor chip and the first conductive portion are electrically connected via the bump.

3. The semiconductor device according to claim 1, further comprising a ball terminal which is provided on a surface of the first redistribution layer opposite to a surface of the first redistribution layer on a side of the encapsulation layer or on the electrode pillar exposed to the first surface of the encapsulation layer and is electrically connected to the first conductive portion.

4. The semiconductor device according to claim 1, wherein a thickness of the first redistribution layer is equal to or less than 0.3 mm.

5. The semiconductor device according to claim 1, further comprising a second redistribution layer which is provided on a second surface opposite to the first surface of the encapsulation layer and includes a second conductive portion electrically connected to a second terminal portion provided on a second surface opposite to the first surface of the semiconductor chip.

6. The semiconductor device according to claim 5, wherein
a current path is formed between the first conductive portion and the second conductive portion with the semiconductor chip interposed therebetween.

7. The semiconductor device according to claim 5, wherein a part of a side surface of the electrode pillar is exposed from a side surface of the encapsulation layer.

8. The semiconductor device according to claim 1, wherein the first redistribution layer includes, in at least a part of a region facing the semiconductor chip, a transmission region made of a transmission material that transmits light from an outside of the first redistribution layer to the semiconductor chip or transmits light emitted from the semiconductor chip to the outside of the first redistribution layer.

9. The semiconductor device according to claim 1, comprising
a plurality of electrode pillars, each being the electrode pillar, which are disposed in the encapsulation layer, wherein
at least two electrode pillars among the plurality of electrode pillars are electrically connected.

10. The semiconductor device according to claim 5, wherein
the semiconductor chip includes, on the first surface facing the first redistribution layer, a semiconductor stacked portion that achieves a function provided by the semiconductor chip, and
a surface of the first redistribution layer opposite to a surface of the first redistribution layer facing the first surface of the encapsulation layer is a mounting surface of the semiconductor device.

11. The semiconductor device according to claim 5, wherein
the semiconductor chip includes, on a second surface opposite to the first surface facing the first redistribution layer, a semiconductor stacked portion that achieves a function provided by the semiconductor chip, and
a surface of the first redistribution layer opposite to a surface of the first redistribution layer facing the first surface of the encapsulation layer is a mounting surface of the semiconductor device.

12. The semiconductor device according to claim 1, wherein the encapsulation layer includes a plurality of semiconductor chips each being the semiconductor chip.

13. The semiconductor device according to claim 12, wherein the plurality of semiconductor chips are stacked in a thickness direction of the encapsulation layer.

14. The semiconductor device according to claim 8, wherein the semiconductor chip includes an optical element.

15. The semiconductor device according to claim 5, wherein
the encapsulation layer has a conductive structural body that is located at a position facing a side surface of the semiconductor chip and is exposed on a side surface of the encapsulation layer.

16. The semiconductor device according to claim 15, wherein
the conductive structural body divides an encapsulation portion encapsulating the semiconductor chip in the encapsulation layer into two regions in at least one of a first cross section of the encapsulation layer intersecting the first surface of the semiconductor chip or a surface on a side of the first redistribution layer.

17. The semiconductor device according to claim 15, wherein
in the conductive structural body, a thickness of another portion exposed on the side surface of the encapsulation layer is thinner than a thickness of one portion facing the side surface of the semiconductor chip.

18. The semiconductor device according to claim 5, wherein the encapsulation layer further includes a conductive structural body that has a first portion facing a side surface of the semiconductor chip and extending in a direction along the side surface of the semiconductor chip, a second portion extending from one end of the first portion in a direction away from the side surface of the semiconductor chip, and a third portion extending from another end of the first portion in a direction away from the side surface of the semiconductor chip.

19. The semiconductor device according to claim 18, wherein a part of the second portion and a part of the third portion are exposed on a side surface of the encapsulation layer, and a thickness of the part of the second portion and a thickness of the part of the third portion are thinner than that of the first portion.

20. A method for manufacturing a semiconductor device, comprising:
forming an encapsulation layer by encapsulating one surface of a temporary support substrate with a resin in a state where a semiconductor chip and an electrode pillar are disposed spaced apart from each other on the one surface of the temporary support substrate;
after the temporary support substrate is peeled off from a first surface of the encapsulation layer, on the first surface of the encapsulation layer,
forming a first redistribution layer which electrically connects a first terminal portion provided on a first surface of the semiconductor chip exposed on the first surface of the encapsulation layer and one end surface of the electrode pillar exposed from the first surface of the encapsulation layer;
grinding the resin until another end surface of the electrode pillar is exposed from a second surface opposite to the first surface of the encapsulation layer; and
forming a second redistribution layer which is electrically connected to the another end surface of the electrode pillar on the second surface of the encapsulation layer from which the another end surface of the electrode pillar is exposed.

21. A method for manufacturing a semiconductor device, comprising:
forming a first redistribution layer on one surface of a temporary support substrate;
forming an electrode pillar, which is electrically connected to the first redistribution layer, on a surface of the first redistribution layer opposite to a surface of the first redistribution layer on a side of the temporary support substrate;
disposing a semiconductor chip, which is electrically connected to the electrode pillar via the first redistribution layer, spaced apart from the electrode pillar on the surface of the first redistribution layer opposite to the surface of the first redistribution layer on the side of the temporary support substrate;
encapsulating, with a resin, the surface of the first redistribution layer opposite to the surface of the first redistribution layer on the side of the temporary support substrate, another end surface of the electrode pillar opposite to one end surface of the electrode pillar on a side of the first redistribution layer, and a surface of the semiconductor chip opposite to a surface of the semiconductor chip on the side of the first redistribution layer in a state where the electrode pillar and the semiconductor chip are disposed spaced apart from each other;
grinding the resin until the another end surface of the electrode pillar is exposed; and
after the temporary support substrate is peeled from the first redistribution layer, forming a second redistribution layer, which is electrically connected to the electrode pillar, on a surface of the resin opposite to a surface of the resin on the side of the first redistribution layer, the another end surface of the electrode pillar, and the surface of the semiconductor chip opposite to the surface of the semiconductor chip on the side of the first redistribution layer.
